(19) United States
(12) Patent Application Publication
(10) Pub. No.: US 2026/0066029 A1
(43) Pub. Date: Mar. 5, 2026

(54) MEMORY INTEGRITY CONFIRMATION DEVICE, INFORMATION PROCESSING DEVICE, AND MEMORY INTEGRITY CONFIRMATION METHOD

(71) Applicant: NEC Corporation, Tokyo (JP)

(72) Inventors: Jun FURUKAWA, Tokyo (JP); Satsuya Ohata, Tokyo (JP)

(73) Assignee: NEC Corporation, Tokyo (JP)

(21) Appl. No.: 19/310,063

(22) Filed: Aug. 26, 2025

(30) Foreign Application Priority Data
Sep. 2, 2024 (JP) 2024-150774

(51) Int. Cl. G11C 29/44

(52) U.S. Cl. CPC G11C 29/44

(57) ABSTRACT

Provided are a memory integrity confirmation device capable of preventing occurrence of deadlock. The memory integrity confirmation device includes a tree cache that temporarily stores data allocated to a node in an integrity tree including nodes arranged in a tree shape, and a request processing unit that receives a request for a leaf node in the integrity tree from the cache memory and requests the tree cache to search for an intermediate node from the leaf node to a root node in the integrity tree, in which the tree cache locks the intermediate node for exclusively controlling a request for searching for the same intermediate node and includes a first registration unit that registers a wait request for each locked intermediate node, and the request processing unit includes a first block unit that blocks a request accepted by the request processing unit.

### INCORPORATION BY REFERENCE

This application is based upon and claims the benefit of priority from Japanese patent application No. 2024-150774, filed on Sep. 2, 2024, the disclosure of which is incorporated herein in its entirety by reference.

### TECHNICAL FIELD

The present disclosure relates to a memory integrity confirmation device, an information processing device, a memory integrity confirmation method, and a program.

### BACKGROUND ART

In an information processing device mounted on a computer and the like, storage areas such as a register, a cache, a memory, and a storage are hierarchized. Here, in the data transfer between the cache and the memory, integrity confirmation of data and encryption processing (encryption and decryption or any one thereof) of data in some cases are performed. As a result, it is possible to prevent leakage of data stored in the information processing device due to a physical attack on the information processing device from the outside. Hereinafter, data integrity confirmation performed in data transfer between the cache and the memory is also referred to as memory integrity confirmation processing. In a case where data encryption is added, it is also referred to as memory encryption with integrity confirmation.

In recent years, development of data integrity confirmation method using an integrity tree composed of a plurality of nodes arranged in a tree shape, linked to each of which a combination of a counter and an identifier is allocated, is underway. In the integrity confirmation processing using the integrity tree, not only the data allocated to the leaf node which is the node at the lowest layer among the plurality of nodes constituting the integrity tree is verified, but also the authenticators (tags) allocated to all the nodes existing on the path from the leaf node to the root node are verified. This integrity confirmation of data combined with data encryption, prevents data forgery and unauthorized reuse of past data, thereby data processing based on unintended data is prevented. Therefore, the risk of data leakage is further reduced, and confidentiality is improved. A technique related to data authentication using an integrity tree is disclosed in, for example, Patent Literature 1.

### CITATION LIST

### Patent Literature

[Patent Literature 1] JP 2020-529657 A

### SUMMARY

As in Patent Literature 1 and the like, in the integrity confirmation processing using the integrity tree, an address space covered by the integrity tree is a target of the integrity confirmation processing. In other words, the address space allocated to each of the plurality of leaf nodes which are nodes at the lowest layer among the plurality of nodes constituting the integrity tree is the final target of the integrity confirmation processing. Thus, certain leaf node and another leaf node may be hanging from a common ancestor node. Therefore, in a case where an access to data allocated to a certain leaf node and an access to data allocated to another leaf node are performed in parallel, there is a possibility that update processing of a common ancestor node by these accesses collide.

In order to avoid such a collision, a method of locking a node being accessed and blocking processing on the node by another access is conceivable. However, in this case, a series of processing for a necessary node cannot be completed, and the integrity confirmation processing may be deadlocked.

In view of the above-described problems, an example object of the present disclosure is to provide a memory integrity confirmation device, an information processing device, a memory integrity confirmation method, and a program capable of preventing the occurrence of deadlock.

A memory integrity confirmation device according to an example aspect of the present disclosure is a memory integrity confirmation device that confirms integrity of data between a cache memory and a memory. The memory integrity confirmation device includes a tree cache that temporarily stores data allocated to nodes in an integrity tree including the nodes arranged in a tree shape, and a request processing unit that accepts a request for a leaf node in the integrity tree from the cache memory and requests the tree cache to search for an intermediate node from the leaf node to a root node in the integrity tree. The tree cache includes a first registration unit that locks the intermediate node to exclusively control the search request for a same intermediate node, and registers a wait request for each locked intermediate node. The request processing unit includes a first block unit that blocks a request accepted by the request processing unit in accordance with a number of the registered wait requests in the first registration unit.

An information processing device according to an example aspect of the present disclosure includes a cache memory, a memory, and a memory integrity confirmation unit that confirms integrity of data between the cache memory and the memory. The memory integrity confirmation unit includes a tree cache that temporarily stores data allocated to nodes in an integrity tree including the nodes arranged in a tree shape, and a request processing unit that accepts a request for a leaf node in the integrity tree from the cache memory and requests the tree cache to search for an intermediate node from the leaf node to a root node in the integrity tree. The tree cache includes a first registration unit that locks the intermediate node to exclusively control the search request for a same intermediate node, and registers a wait request for each locked intermediate node. The request processing unit includes a first block unit that blocks a request accepted by the request processing unit in accordance with a number of the registered wait requests in the first registration unit.

A memory integrity confirmation method according to an example aspect of the present disclosure is a memory integrity confirmation method for confirming integrity of data between a cache memory and a memory, the method including temporarily storing, by a tree cache, data allocated to nodes in an integrity tree including the nodes arranged in a tree shape, accepting, by a request processing unit, a request for a leaf node in the integrity tree from the cache memory and requesting the tree cache to search for an intermediate node from the leaf node to a root node in the integrity tree, locking the intermediate node to exclusively control the search request for a same intermediate node, and registering a wait request for each locked intermediate node, and blocking a request accepted by the request processing unit in accordance with a number of the registered wait requests.

A program according to an example aspect of the present disclosure is a program for confirming integrity of data between a cache memory and a memory, the program causing a computer to execute temporarily storing, by a tree cache, data allocated to nodes in an integrity tree including the nodes arranged in a tree shape, receiving, by a request processing unit, a request for a leaf node in the integrity tree from the cache memory, requesting the tree cache to search for an intermediate node from the leaf node to a root node in the integrity tree, locking the intermediate node to exclusively control a request for the search for the same intermediate node, registering a wait request for each locked intermediate node, and blocking a request received by the request processing unit according to the number of registered standby requests.

According to the present disclosure, it is possible to prevent the occurrence of deadlock.

### BRIEF DESCRIPTION OF DRAWINGS

The above and other aspects, features and advantages of the present disclosure will become more apparent from the following description of certain exemplary embodiments when taken in conjunction with the accompanying drawings, in which:

FIG. 1 is a block diagram illustrating a configuration example of a memory integrity confirmation device according to some example embodiments;

FIG. 2 is a block diagram illustrating a configuration example of an information processing device including a memory integrity confirmation unit according to some example embodiments;

FIG. 3 is a conceptual diagram illustrating a configuration example of an integrity tree according to some example embodiments;

FIG. 4 is a diagram illustrating a relationship between each node constituting an integrity tree according to some example embodiments and a cache line relevant to each node;

FIG. 5 is a diagram for explaining parallel processing of integrity confirmation processing using an integrity tree according to some example embodiments;

FIG. 6 is a diagram for explaining parallel processing of integrity confirmation processing using an integrity tree according to some example embodiments;

FIG. 7 illustrates an exemplary structure of data registered in the MSHR according to some example embodiments;

FIG. 8 is a block diagram illustrating a detailed configuration example of a PAT requester according to some example embodiments;

FIG. 9 is a block diagram illustrating a detailed configuration example of a PAT cache according to some example embodiments;

FIG. 10 is a block diagram illustrating a detailed configuration example of an authenticator according to some example embodiments;

FIG. 11 is a block diagram illustrating a detailed configuration example of a verifier according to some example embodiments;

FIG. 12 is a block diagram illustrating a detailed configuration example of a memory requester according to some example embodiments;

FIG. 13 is a flowchart illustrating an operation example of a PAT requester according to some example embodiments;

FIG. 14 is a flowchart illustrating an operation example of the PAT cache according to some example embodiments;

FIG. 15 is a flowchart illustrating an operation example of the PAT cache according to some example embodiments;

FIG. 16 is a flowchart illustrating an operation example of the PAT cache according to some example embodiments;

FIG. 17 is a flowchart illustrating an operation example of an authenticator according to some example embodiments;

FIG. 18 is a flowchart illustrating an operation example of an authenticator according to some example embodiments;

FIG. 19 is a flowchart illustrating an operation example of a verifier according to some example embodiments;

FIG. 20 is a flowchart illustrating an operation example of a memory requester according to some example embodiments;

FIG. 21 is a flowchart illustrating an operation example of a memory requester according to some example embodiments; and

FIG. 22 is a configuration diagram illustrating an example of a hardware configuration of a computer according to some example embodiments.

### EXAMPLE EMBODIMENTS

Hereinafter, example embodiments will be described with reference to the drawings. In the drawings, the same elements are denoted by the same reference signs, and redundant description will be omitted as necessary. Arrows illustrated in the drawings are examples for description, and do not limit types and directions of signals (data).

### (Review of Related Art)

As described above, the computer has a memory hierarchy represented by a series of register-cache-memory-storage. In the memory integrity confirmation processing, an authenticator is added during data sending from the cache to the memory, and the integrity of the data is verified during reading the data after being written from the memory to the cache.

The inventor has studied a method of processing a cache of auxiliary data for confirming memory integrity in parallel. As described above, in the integrity confirmation processing using the integrity tree, in a case where the access to the data allocated to a certain leaf node and the access to the data allocated to another leaf node are performed in parallel, there is a possibility that the update processing of the common ancestor node by these accesses will collide.

In order to avoid such a state, in the integrity confirmation processing using the integrity tree, in a case where access (first access) to data allocated to a certain leaf node (first node) and subsequent access (second access) to data allocated to another leaf node (second node) are performed, the following processing is executed.

First, along with the first access, all the nodes existing on the path from the first node to a node firstly cached with a cache line among nodes existing on the path from the first node to the root node are locked, and then the locked node is updated. With the second access, all the nodes existing on the path from the second node to a node firstly cached with a cache line among nodes existing on the path from the second node to the root node are locked, and then the locked node is updated. Here, in a case where a third node (that is, a common ancestor node), which is a node already locked due to the first access, exists in a node existing on a path from the second node to the root node, all the nodes existing on the path from the second node to a node immediately before the third node are locked, and after all the nodes locked due to the first access are unlocked, the remaining nodes existing on the path from the third node to a node firstly cached with a cache line among nodes existing on the path from the third node to the root node are locked, and then the locked node is updated.

In a related art, the lock is performed by using a mechanism called a miss status holding register (MSHR). That is, in locking a certain node, an identifier (address) of the node is registered in the MSHR. In a case where there is a new access to the registered node, the node is written in an access waiting list related to the address of the node. In the above example, the third node is locked by access by the first node. That is, the third node is registered in the MSHR. Then, in a case where the second access accesses the third node, it is already locked and is written in its waiting list. Then, in a case where the first access ends the process and the third node is unlocked, the access source listed in the waiting list is permitted to access the third node (updated in this case).

The MSHR has a limited number of nodes that can be registered, and the length of a waiting list for each registered node is also limited. The smaller the number and length, the smaller the circuit size and the faster the operation time. Due to such limitations, in a case where the number of nodes to register reaches a limit, the cache of nodes in the integrity tree is blocked so that no further registration is required. This cache is also blocked in a case where the waiting list of a certain registered node is full.

However, blocking occurring in the above two types of cases may cause deadlock in a case where the caches are operated in parallel. For example, it is assumed that after the first access locks the third node, the second access accesses the third node, so that the waiting list for the third node is overflowed and the cache is blocked. At this time, if the first access does not access all the required nodes and an access to a further cache is required, the access is not completed due to the blocking described above. As a result, a series of processes on a necessary node cannot be completed, and the locked third node cannot be released. Unless the third node is released, the access source registered in the waiting list related to the third node cannot be allowed to access the node, and the waiting list cannot be released. That is, the accompanying blocking cannot be released. Therefore, in the related technology, there is a problem that the entire processing of the memory integrity confirmation processing falls into deadlock.

### First Example Embodiment

Next, a first example embodiment will be described. In the present example embodiment, an outline of some example embodiments will be described.

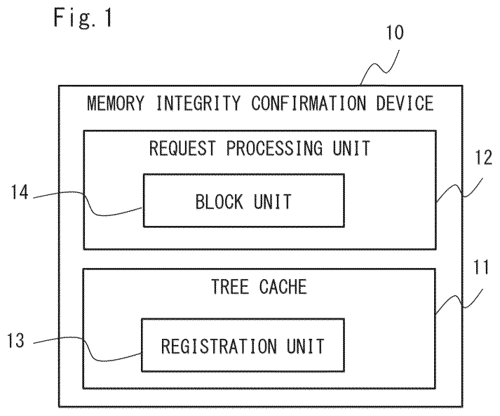

FIG. 1 is a block diagram illustrating a configuration example of a memory integrity confirmation device 10 according to some example embodiments. The memory integrity confirmation device 10 is a device that confirms integrity of data between a cache memory and a memory (main memory). The integrity of data means that data read and written between the cache memory and the memory is consistent, that is, data is not tampered with. For example, a cache memory, a memory, and the memory integrity confirmation device 10 may constitute the information processing device.

In the example of FIG. 1, the memory integrity confirmation device 10 includes a tree cache 11 and a request processing unit 12.

The memory integrity confirmation device 10 performs integrity confirmation processing using an integrity tree including nodes arranged in a tree shape. The tree cache 11 temporarily stores data allocated to nodes in the integrity tree.

The request processing unit 12 accepts a request for a leaf node in the integrity tree from the cache memory. The request processing unit 12 requests the tree cache 11 to search for an intermediate node from the leaf node to the root node in the integrity tree in order to confirm the integrity of the data of the leaf node.

The request processing unit 12 may accept other requests. For example, the request processing unit 12 may accept a cache eviction request from the tree cache 11. In this case, the request processing unit 12 may execute the request from the tree cache 11 over the request from the cache memory. The request processing unit 12 may accept an update request of the counter allocated to the node from the authentication unit that generates an authentication tag allocated to the node. In this case, the request processing unit 12 may execute the request from the authentication unit over the request from the cache memory. In a case where a request for searching for the tree cache 11 for an intermediate node and another request conflict with each other, the request processing unit 12 may preferentially execute the request for searching for the intermediate node over the another request.

The tree cache 11 includes a registration unit (for example, a first registration unit) 13. The registration unit 13 locks the intermediate node in order to exclusively control a search request for the same intermediate node. For example, the registration unit 13 is an MSHR that registers a request in the tree cache. That is, by registering the requested intermediate node in the MSHR, the intermediate node is locked, and other accesses to the same intermediate node are prohibited. Further, the registration unit 13 registers a wait request for each locked intermediate node. For example, in a case where there is a new request to the intermediate node registered in the MSHR, the new request is written as a wait request in the waiting list for each intermediate node, and is set to the waiting state.

The request processing unit 12 includes a block unit (for example, a first block unit) 14. The block unit 14 blocks a request to the request processing unit 12. The block unit 14 blocks the request accepted by the request processing unit 12 according to the number of wait requests registered in the registration unit 13 of the tree cache 11. For example, the block unit 14 may block the request accepted by the request processing unit 12 in a case where the number of wait requests registered in the registration unit 13 is larger than a predetermined threshold. For example, the predetermined threshold is a value with which a shortage of the list of wait requests can be expected, and is smaller than the maximum value of the number of wait requests that can be registered in the registration unit 13 (MSHR).

The tree cache 11 may include a block unit (for example, a second block unit) that blocks a request for the tree cache 11. In a case where the tree cache 11 and the request processing unit 12 each include a block unit, any block unit may be the first block unit or the second block unit. The block unit of the tree cache 11 may block the request accepted in the tree cache 11 according to the number of intermediate nodes locked in the registration unit 13. For example, in a case where the number of intermediate nodes locked by the registration unit 13 reaches the upper limit (the maximum value of the number of intermediate nodes that can be locked by the registration unit 13), the block unit of the tree cache 11 may block the request accepted in the tree cache 11.

The request processing unit 12 may include a registration unit (for example, a second registration unit) that registers a leaf node. In a case where the tree cache 11 and the request processing unit 12 each include a registration unit, any registration unit may be the first registration unit or the second registration unit. The registration unit of the request processing unit 12 locks the leaf node in order to exclusively control a request from the cache memory for the same leaf node. Further, the registration unit of the request processing unit 12 registers the wait request for each locked leaf node. For example, the registration unit of the request processing unit 12 is an MSHR that registers a request in the request processing unit 12. For example, the block unit 14 may block the request accepted by the request processing unit 12 according to the number of leaf nodes locked in the registration unit of the request processing unit 12 or the number of wait requests registered in the registration unit of the request processing unit 12. In a case where the number of leaf nodes locked in the registration unit of the request processing unit 12 reaches an upper limit (a maximum value of the number of leaf nodes that can be locked in the registration unit of the request processing unit 12) or in a case where the number of wait requests registered in the registration unit of the request processing unit 12 reaches an upper limit (a maximum value of the number of wait requests that can be registered in the registration unit of the request processing unit 12), the block unit 14 may block the request accepted in the request processing unit 12.

As described above, the memory integrity confirmation device that performs the integrity confirmation processing using the integrity tree includes the request processing unit that accepts the request from the cache memory and the tree cache that accepts the request from the request processing unit. Furthermore, the tree cache includes a registration unit (MSHR) that locks requests to the same intermediate node, and the request processing unit blocks requests accepted by the request processing unit according to the number of wait requests in the registration unit. As a result, the request input to the request processing unit can be blocked before the list of wait requests in the registration unit reaches the upper limit. At this time, since the request input to the tree cache is not blocked, it is possible to process the request input to the tree cache from the request processing unit. Therefore, it is possible to continue the integrity tree search processing (a series of processing on the upper node of the leaf node) between the request processing unit and the tree cache without increasing new processing by the request to the request processing unit, and thus, it is possible to prevent the occurrence of deadlock.

### Second Example Embodiment

Next, a second example embodiment will be described. In the present example embodiment, a specific example of the first example embodiment will be described.

### <Schematic Configuration of Information Processing Device>

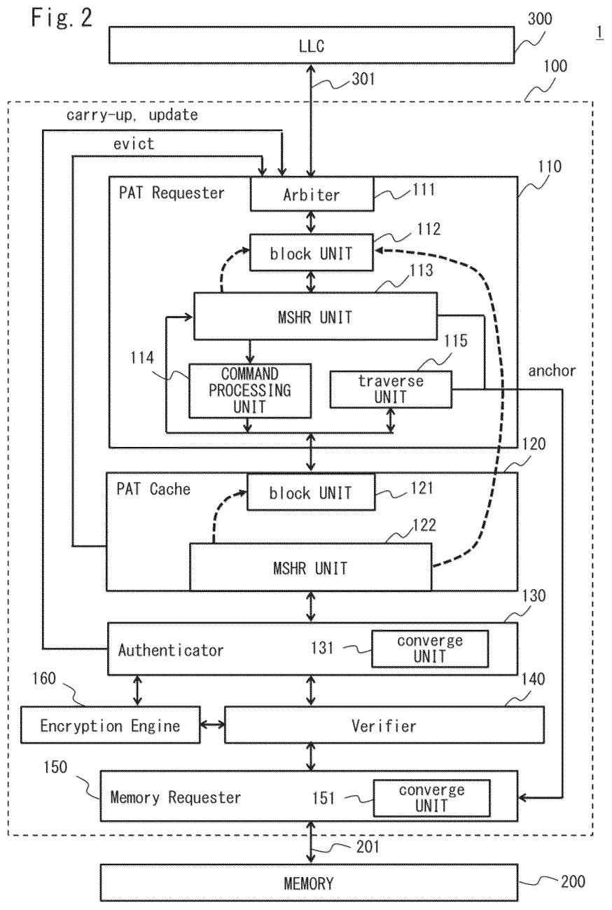

First, a schematic configuration of an information processing device will be described. FIG. 2 is a block diagram illustrating a configuration example of an information processing device 1 including a memory integrity confirmation unit 100 according to some example embodiments. In the example of FIG. 2, the information processing device 1 includes a memory integrity confirmation unit 100, a memory 200, and a last level cache (LLC) 300. The information processing device 1 further includes a processor, a primary cache, a secondary cache, and the like as necessary.

The memory 200 is a main memory that stores data used by the processor. The LLC 300 is a cache memory that temporarily stores data on the memory 200 and provides the data on the memory 200 to the processor at a high speed. The LLC 300 is a cache memory closest to the memory 200 among cache memories.

The memory integrity confirmation unit 100 is installed between the memory 200 and the LLC 300. The memory integrity confirmation unit 100 and the memory 200 are connected by a memory bus 201. The memory integrity confirmation unit 100 and the LLC 300 are connected by an LLC bus 301. The memory integrity confirmation unit 100 performs memory integrity confirmation processing using an integrity tree between the memory 200 and the LLC 300. The memory integrity confirmation unit 100 can perform parallel processing on a plurality of requests from the LLC 300.

As the memory integrity confirmation processing, the memory integrity confirmation unit 100 performs memory integrity authentication processing on data to be written from the cache (LLC 300) to the memory 200, for data to be transferred between the LLC 300 and the memory 200. The memory integrity authentication processing also has an option of adding encryption processing. The memory integrity confirmation unit 100 performs memory integrity verification processing on data read from the memory 200 into the cache (LLC 300) as the memory integrity confirmation processing. The memory integrity verification processing also has an option of adding a decoding processing. In the memory integrity authentication processing and the memory integrity verification processing, an integrity tree including a plurality of nodes arranged in a tree shape is used. Each node of the integrity tree is allocated a set of counters and identifiers.

Here, in the integrity confirmation processing using the integrity tree, not only the data allocated to the leaf node which is the node at the lowest layer among the plurality of nodes constituting the integrity tree is authenticated or verified, but also the authenticators (authentication tags) allocated to all the nodes existing on the path from the leaf node to the root node are verified. As a result, the risk of data leakage is reduced, so that confidentiality is improved. The authentication tag allocated to each node is generated using a counter, an identifier, and the like allocated to the node.

In the example of FIG. 2, the memory integrity confirmation unit 100 includes a PAT requester 110, a PAT cache 120, an authenticator 130, a verifier 140, a memory requester 150, and an encryption engine 160. PAT is an abbreviation of parallelizable authentication tree.

A PAT requester (PAT request processing unit) 110 accepts a request to read data from the memory 200 and a request to write data to the memory 200 from the LLC 300 (LLC bus 301). For example, the PAT requester 110 is relevant to the request processing unit 12 in FIG. 1. The PAT requester 110 also accepts a command (evict, carry-up, update) request from the PAT cache 120 or the authenticator 130. The PAT requester 110 sends the node and the request to the PAT cache 120 and the memory requester 150 based on the accepted request. For example, the PAT requester 110 includes an arbiter 111, a block unit 112, an MSHR unit 113, a command processing unit 114, and a traverse unit 115. For example, the block unit 112 is relevant to the block unit 14 in FIG. 1. Details of each unit of the PAT requester 110 will be described later.

The PAT cache 120 is a storage unit that caches data allocated to each node of the integrity tree. Specifically, the PAT cache 120 is a cache that temporarily stores a part of the counter and the identifier allocated to each node of the integrity tree and the tag generated using the counter and the identifier. For example, the PAT cache 120 is relevant to the tree cache 11 of FIG. 1. The PAT cache 120 searches for a cached node, requests the authenticator 130, and the like in response to a request from the PAT requester 110. For example, the PAT cache 120 includes a block unit 121 and an MSHR unit 122. For example, the MSHR unit 122 is relevant to the registration unit 13 in FIG. 1. Details of each unit of the PAT cache 120 will be described later.

The authenticator (authentication unit) 130 generates an authentication tag for a node written in the memory 200. The authenticator 130 generates an authentication tag according to a cryptographic protocol by using the encryption engine 160. The encryption engine 160 encrypts or decrypts the input information according to a predetermined encryption scheme. For example, the authenticator 130 includes a converge unit 131. Details of each unit of the authenticator 130 will be described later.

The verifier (verification unit) 140 verifies the node read from the memory 200. The verifier 140 verifies the node (data) read according to the cryptographic protocol by using the encryption engine 160. Details of each unit of the verifier 140 will be described later.

The memory requester (memory request unit) 150 requests the memory 200 (memory bus 201) to read data and write data. For example, the memory requester 150 includes a converge unit 151. Details of each unit of the memory requester 150 will be described later.

### <Configuration of Integrity Tree>

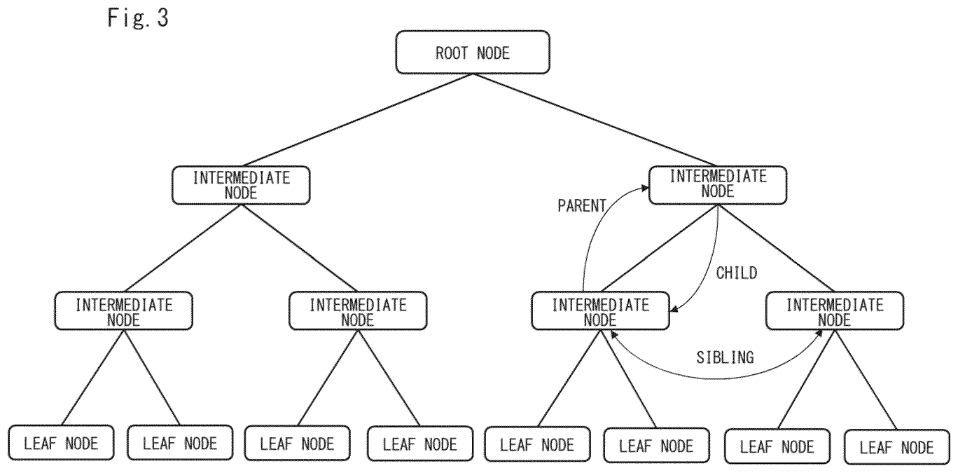

FIG. 3 is a conceptual diagram illustrating a configuration example of an integrity tree according to some example embodiments. As illustrated in FIG. 3, the integrity tree is configured by associating a plurality of nodes in a tree shape. Among the plurality of nodes constituting the integrity tree, a node at the highest layer is referred to as a root node, a node at the lowest layer is referred to as a leaf node, and a node between the root node and the leaf node is referred to as an intermediate node. In the tree structure, a node higher than a certain node is referred to as a parent node, a node lower than the certain node is referred to as a child node, and two nodes having the same parent node are referred to as sibling nodes.

An address space covered by the integrity tree is a target of the memory integrity confirmation processing of the memory integrity confirmation unit 100. In other words, the address space allocated to each of the plurality of leaf nodes which are nodes at the lowest layer among the plurality of nodes constituting the integrity tree is a target of the memory integrity confirmation processing. In a case where encryption is involved, it is also a target of encryption. Hereinafter, only a case where encryption and decryption are involved will be considered. It is obvious that in a case where these are not involved, the encryption with authentication to be used may be changed to simple authentication processing.

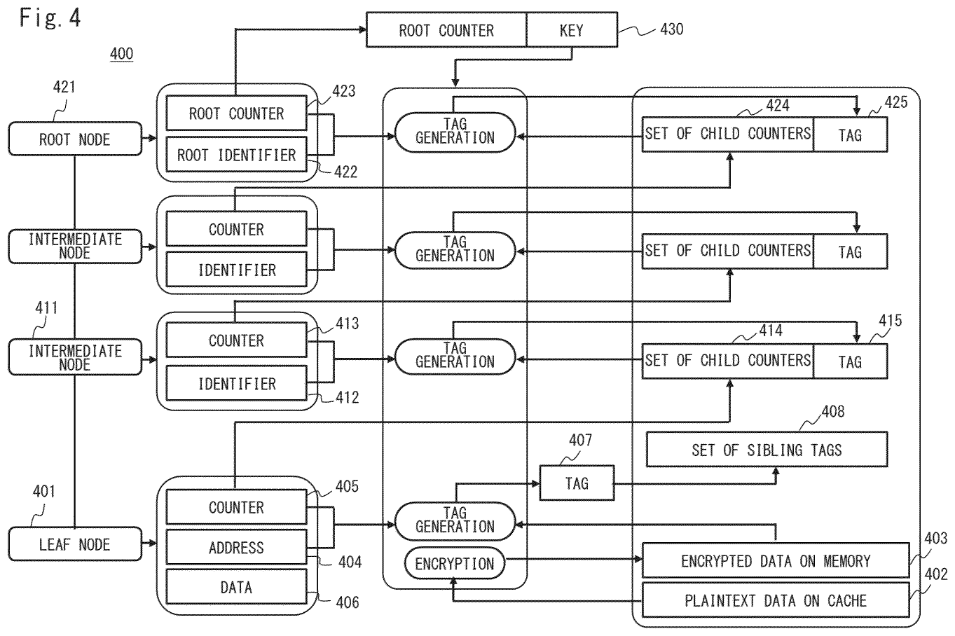

FIG. 4 is a diagram illustrating a relationship between each node constituting an integrity tree and a cache line relevant to each node according to some example embodiments.

In the example of FIG. 4, the integrity tree 400 includes a leaf node 401, an intermediate node 411, and a root node 421. A data block is allocated to each node. A unit of data block allocated to each node is referred to as a cache line. The PAT cache 120 stores a cache line (data block) allocated to each node.

It is assumed that each cache line is provided with at least a bit indicating either dirty or clean. The “clean” indicates that the cache line stored in the PAT cache 120 is the same as the associated cache line stored in the memory 200. The “dirty” indicates that the cache line stored in the PAT cache 120 is updated and is different from the associated cache line stored in the memory 200.

A counter and an identifier are allocated to each node. A counter 405 and an address 404 are allocated to each leaf node 401. That is, the identifier of each leaf node 401 is the address 404 of the relevant cache line.

A counter 413 and an identifier 412 are allocated to each intermediate node 411. The identifier 412 of each intermediate node 411 is derivable from its position in the integrity tree 400. For example, the identifier 412 allocated to the parent node (intermediate node 411) of the leaf node 401 specified by a certain address 404 can be derived from the address 404 of the leaf node 401.

Similarly to the intermediate node 411, a root counter 423 and a root identifier 422 are allocated to the root node 421. A key 430 is associated with the root counter 423.

In addition, data 406 associated with the address (identifier) 404 is allocated to each leaf node 401. In a case where data 406 is written to the data cache (LLC 300), the data matches the cache line written to the data cache. The cache line written to the data cache includes only data 406.

In any leaf node 401, encrypted data (hereinafter, also simply referred to as ciphertext) 403 is generated by plaintext data 402 of the relevant cache line and the key 430, and an authentication tag (authenticator, MAC (Message Authentication Code)) 407 is generated by the ciphertext 403, the address 404 of the leaf node 401, the value of the counter 405 of the leaf node 401, and the key 430. The authentication tag may be simply referred to as a tag. The authentication tag 407 generated in the leaf node 401 is stored in a cache line 408 (a set of tags of sibling nodes) different from the cache line of the plaintext data 402 together with an authentication tag generated in another node (sibling node) having a common parent node with the leaf node 401.

In a case where a cache line allocated to the leaf node 401 is written from the data cache (LLC 300) to the memory 200, the ciphertext 403 generated by encrypting the plaintext data 402 is written to the memory 200 instead of the plaintext data 402.

On the other hand, in a case where the cache line allocated to the leaf node 401 is read from the memory 200 into the data cache, first, a tag is generated by the address 404 of the leaf node 401, the value of the counter 405 of the leaf node 401, the ciphertext 403 read from the memory 200, and the key 430. Then, only in a case where the generated tag matches the tag 407 stored in the cache line 408, the ciphertext 403 read from the memory 200 is decrypted into the plaintext data 402 by the key 430 and then read into the data cache as the cache line of the leaf node 401. At this time, the value of the counter 405 of the leaf node 401 needs to be included in the cache line of the parent node (intermediate node 411) and exist in the PAT cache 120.

In any intermediate node 411, a tag 415 is generated by the value of the counter 414 for each of all child nodes of the intermediate node 411, the value of the counter 413 of the intermediate node 411, the identifier 412 of the intermediate node 411, and the key 430. The cache line allocated to the intermediate node 411 includes the values of the counters 414 of all the child nodes of the intermediate node 411 and the tag 415 generated in the intermediate node 411.

In a case where the cache line allocated to the intermediate node 411 is written out from the PAT cache 120 to the memory 200, the authentication tag included in the cache line needs to be generated using the values of the counters of all the child nodes included in the cache line. In other words, after the tag included in the cache line is generated, the value of the counter of any child node included in the cache line must not be updated.

On the other hand, in a case where the cache line allocated to the intermediate node 411 is read from the memory 200 to the PAT cache 120, first, an authentication tag is generated by the value of the counter 414 of each of all the child nodes of the intermediate node 411 included in the cache line read from the memory 200, the value of the counter 413 of the intermediate node 411, the identifier 412 of the intermediate node 411, and the key 430. Then, only in a case where the generated authentication tag matches the authentication tag included in the cache line allocated to the intermediate node 411, the cache line read from the memory 200 is read by the PAT cache 120. At this time, the value of the counter 413 of the intermediate node 411 needs to be included in the cache line of the parent node and exist in the PAT cache 120.

In the root node 421, an authentication tag 425 is generated by the value of the counter 424 of each of all the child nodes of the root node 421, the value of the counter (root counter) 423 of the root node 421, the identifier (root identifier) 422 of the root node 421, and the key 430. The cache line allocated to the root node 421 is configured by the values of the counters 424 of all the child nodes of the root node 421 and the authentication tag 425 generated in the root node 421.

The value of the counter allocated to any node is updated in the following cases. In a case where a cache line allocated to an arbitrary node is written out from the data cache (LLC 300) or the PAT cache 120 to the memory 200, and the cache line has been updated since the cache line is read from the memory 200 to the data cache or the PAT cache 120, the value of the counter allocated to the node is updated, and then the authentication tag included in the cache line allocated to the node is updated. Thereafter, the updated cache line is written out from the data cache or the PAT cache 120 to the memory 200.

In a case where data (cache line) allocated to an arbitrary leaf node 401 is updated, basically, the values of the counters of all the nodes provided on the path from the leaf node 401 to the root node 421 are counted up. Herein, the counter (root counter) 423 allocated to the root node 421 is specially protected from being directly operated by an attacker. Then, a tag of the relevant node is updated based on the counter 423 of the root node 421, the counter 413 of each intermediate node 411, or the counter 405 of each leaf node 401 and the data 406. As a result, tags of the nodes follow the latest state.

The counter allocated to each node of the integrity tree may include a major counter whose value is represented by an upper bit and a minor counter whose value is represented by a lower bit among a plurality of bits representing the value of the counter. In this case, the major counter allocated to a certain node is shared by other nodes (that is, the sibling node) having a common parent node. As a result, an increase in scale due to the counter is suppressed. In the cache line of a certain intermediate node, the values of a plurality of minor counters allocated to all the child nodes of the intermediate node and the value of one major counter shared by all the child nodes of the intermediate node are stored as the values of the counters. Hereinafter, the counter including the major counter and the minor counter is also referred to as a split counter.

In a case where the counter allocated to each node is a split counter, the value of the minor counter is updated, or the value of the minor counter is initialized and then the value of the major counter is updated. In a case where the major counter is updated, the value of the minor counter allocated to each of all the nodes sharing the major counter is initialized.

### <Specific Example of Parallel Processing>

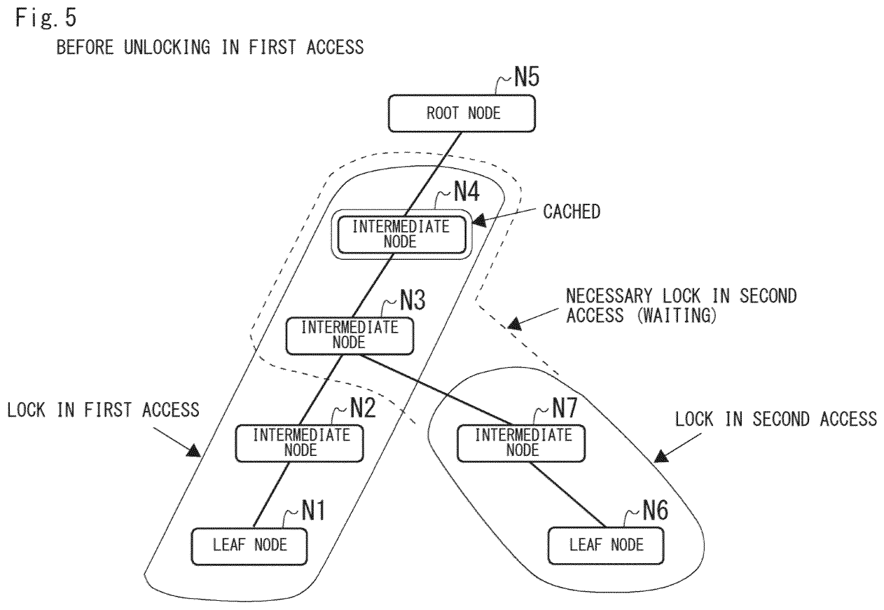

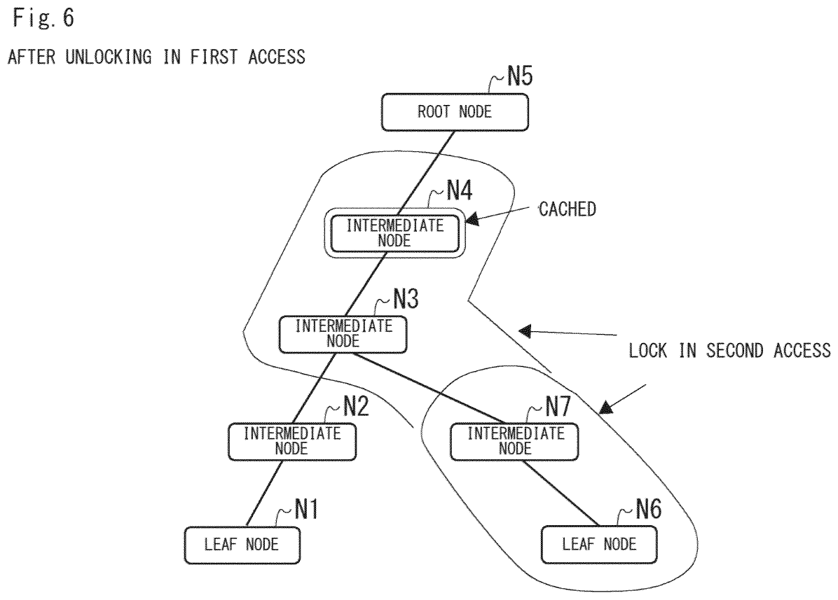

Next, a specific example of parallel processing of the integrity confirmation processing using the integrity tree will be described with reference to FIGS. 5 and 6. FIGS. 5 and 6 are diagrams for explaining parallel processing of integrity confirmation processing using an integrity tree according to some example embodiments.

The integrity confirmation processing using the integrity tree is required to improve processing capability by parallelizing data access. However, in a case where the access to the data allocated to certain leaf node and the access to the data allocated to another leaf node are performed in parallel, there is a possibility that the update processing of the common ancestor node collides with these leaf nodes due to these accesses.

In order to avoid such a state, in the integrity confirmation processing using the integrity tree in the memory integrity confirmation unit 100, in a case where access (first access) to data allocated to a certain leaf node (first node) and subsequent access (second access) to data allocated to another leaf node (second node) are performed, the following processing is executed.

First, as illustrated in FIG. 5, the memory integrity confirmation unit 100 locks all the nodes N1 to N4 existing on the path from the leaf node N1 to the node N4 firstly cached with the cache line among the nodes existing on the path from the leaf node N1 to the root node N5 along with the first access, and then updates the locked nodes N1 to N4.

Next, along with the second access, the memory integrity confirmation unit 100 attempts to lock all the nodes N6, N7, N3, and N4 existing on the path from the leaf node N6 to the node N4 firstly cached with the cache line among the nodes existing on the path from the leaf node N6 to the root node N5. However, in the node existing on the path from the leaf node N6 to the node N4, there is a node N3 (common ancestor node) already locked due to the first access. In this case, the memory integrity confirmation unit 100 first locks all the nodes N6 and N7 existing on the path from the leaf node N6 to the node N7 immediately before the node N3.

Next, as illustrated in FIG. 6, after the nodes N1 to N4 locked with the first access are unlocked, the memory integrity confirmation unit 100 locks the remaining nodes N3 and N4 existing on the path from the node N3 to the node N4 and updates the locked nodes N6, N7, N3, and N4.

### <Data Structure of MSHR>

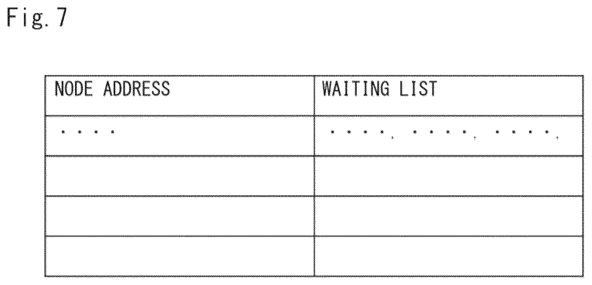

In order to achieve the lock in the parallel processing as described above, the memory integrity confirmation unit 100 uses the MSHR. Specifically, the MSHR unit 113 of the PAT requester 110 locks the node requested to the PAT requester 110, and the MSHR unit 122 of the PAT cache 120 locks the node requested to the PAT cache 120. FIG. 7 illustrates an exemplary structure of data registered in the MSHR according to some example embodiments.

In the example of FIG. 7, the MSHR stores (registers) an address of a node to be locked, and stores (registers) a waiting list of access (request) for each node to be locked. As illustrated in FIG. 7, the node address and the waiting list for each node address may be registered in the two-dimensional table, or the waiting list may be registered in the queue for each node address.

For example, in a case where an address is registered in the MSHR, the node of the registered address is in a locked state. If the node is registered and locked, the request to the node is on a waiting list and will be in a waiting state until the node is unlocked. If the node is unlocked, a request for a waiting list is performed.

### <Detailed Configuration of Memory Integrity Confirmation Unit>

Next, a detailed configuration of each unit of the memory integrity confirmation unit 100 that performs the integrity confirmation processing using the integrity tree will be described.

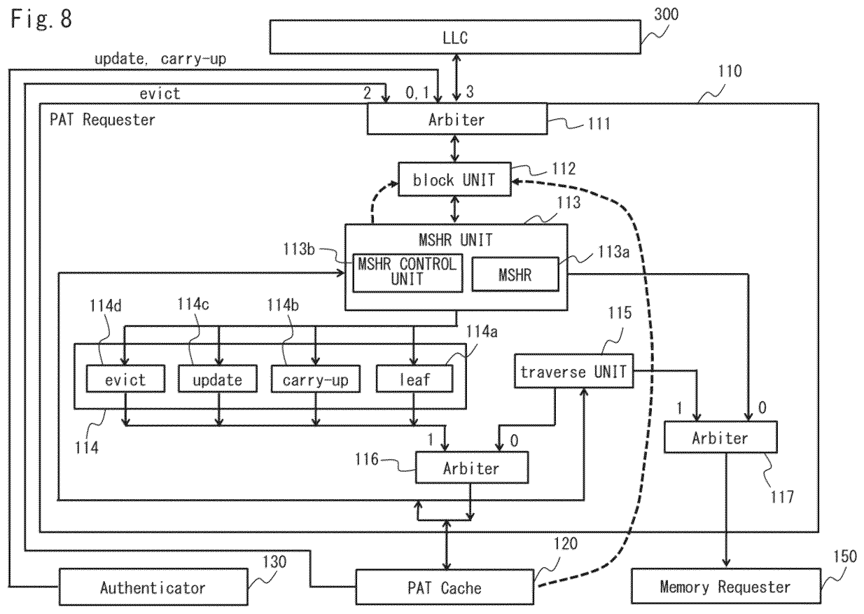

FIG. 8 is a block diagram illustrating a detailed configuration example of the PAT requester 110 according to some example embodiments. In the example of FIG. 8, the PAT requester 110 includes an arbiter 111, a block unit 112, an MSHR unit 113, a command processing unit 114, a traverse unit 115, an arbiter 116, and an arbiter 117.

The arbiter 111 processes the input request according to the priority order. The arbiter 111 accepts a request to read data from the memory 200 and a request to write data to the memory 200 from the LLC 300 (LLC bus 301), and also accepts a command (evict, carry-up, update) request from the PAT cache 120 or the authenticator 130, and in a case where requests conflict with each other, executes each request according to the priority order and sends the request to the block unit 112. In FIG. 8, the number described in the input of the arbiter 111 indicates the priority order. The same applies to other arbiters. For example, the priority order of each request is set in the order of the update request, the carry-up request, the evict request, and the request from the LLC 300 in descending order.

The block unit 112 blocks (discards) or passes the input request according to the set state (block state/non-block state). The block unit 112 blocks the request from the arbiter 111 in the block state (blocking), and sends the request from the arbiter 111 to the MSHR unit 113 in the case of not being in the block state.

The MSHR unit 113 is a registration unit (lock unit) that registers (locks) the node (leaf node) requested to the PAT requester 110. The MSHR unit 113 includes an MSHR 113a and an MSHR control unit 113b. The MSHR 113a stores an address of a node (leaf node) locked by the PAT requester 110 and a waiting list for each address.

The MSHR control unit 113b controls registration of the address of the node and the waiting list in the MSHR 113a. In a case where the requested address (leaf node) is not registered in the MSHR 113a, the MSHR control unit 113b registers the requested address in the MSHR 113a, locks the leaf node, and sends the request to the command processing unit 114. In a case where the number of addresses registered in the MSHR 113a reaches the upper limit, the MSHR control unit 113b sets the block unit 112 to the block state. In other words, in a case where the number of addresses registered in the MSHR 113a reaches the upper limit, the block unit 112 is set to the block state, so that the block unit 112 blocks the request input to the PAT requester 110.

In a case where the requested address (leaf node) is registered in the MSHR 113a, the MSHR control unit 113b describes the request in the waiting list of the relevant address. In a case where the length of the waiting list reaches the upper limit, the MSHR control unit 113b sets the block unit 112 to the block state. In other words, in a case where the length of the waiting list of the MSHR 113a reaches the upper limit, the block unit 112 is set to the block state, so that the block unit 112 blocks the request input to the PAT requester 110.

The command processing unit 114 executes processing of each command and sends a request based on each command to the PAT cache 120. For example, the command processing unit 114 includes a leaf processing unit 114a, a carry-up processing unit 114b, an update processing unit 114c, and an evict processing unit 114d.

The leaf processing unit 114a processes a request from the LLC 300 to a leaf node. The leaf processing unit 114a requests the PAT cache 120 for a leaf node requested by the LLC 300, a node including the counter, and a node including the authentication tag in the case of a read request (the authentication tag is not requested in the case of a write request).

The carry-up processing unit 114b processes the carry-up request from the authenticator 130. The update processing unit 114c processes an update request from the authenticator 130. The evict processing unit 114d processes an evict request from the PAT cache 120.

The traverse unit (search request unit) 115 accepts a response from the PAT cache 120, and transmits a request (node) to the memory requester 150 (arbiter 117) or the PAT cache 120 (arbiter 116) according to the accepted response. In a case where the cache line of the node requested to the PAT cache 120 is hit by the PAT cache 120 or in a case where the node is registered in the MSHR of the PAT cache 120, the traverse unit 115 transmits the response result of the PAT cache 120 to the memory requester 150. In a case where the cache line of the node requested to the PAT cache 120 is not hit by the PAT cache 120 and the node is not registered in the MSHR of the PAT cache 120, the traverse unit 115 extracts the parent node of the node and requests the extracted parent node to the PAT cache 120 (requests the search for the parent node).

The arbiter 116 accepts a request from the command processing unit 114 and a request from the traverse unit 115, and processes the request according to the priority order in a case where the requests conflict with each other. For example, the priority order of the request from the traverse unit 115 is higher than the priority order of the request from the command processing unit 114.

The arbiter 117 accepts a request from the MSHR unit 113 and a request from the traverse unit 115, and processes the request according to the priority order in a case where the requests conflict with each other. For example, the priority order of the request from the MSHR unit 113 is higher than the priority order of the request from the traverse unit 115.

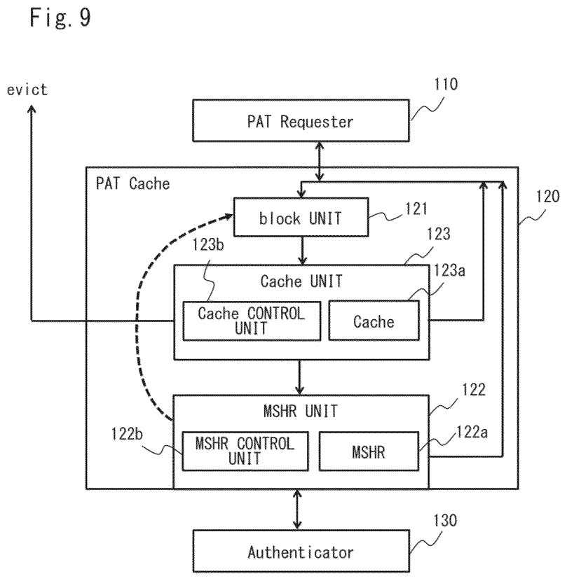

FIG. 9 is a block diagram illustrating a detailed configuration example of the PAT cache 120 according to some example embodiments. In the example of FIG. 9, the PAT cache 120 includes a block unit 121, an MSHR unit 122, and a cache unit 123.

The block unit 121 blocks (discards) or passes the input request according to the set state (block state/non-block state). The block unit 112 blocks the request from the PAT requester 110 in the block state (blocking), and sends the request from the PAT requester 110 to the cache unit 123 in the case of not being in the block state.

The cache unit 123 includes a cache 123a and a cache control unit 123b. The cache 123a caches (stores) data allocated to each node of the integrity tree.

The cache control unit 123b controls caching and searching of data for the cache 123a. If the requested node is not a leaf node, the cache control unit 123b searches for the requested node using the cache 123a. In a case where the requested node is cached, the cache control unit 123b reads the relevant cache line and returns the read result to the PAT requester 110 (sends a response). In a case of updating this node, the cache control unit 123b updates the data cached at the time of reading.

The MSHR unit 122 is a registration unit (lock unit) that registers (locks) a node (intermediate node) requested to the PAT cache 120. The MSHR unit 122 includes an MSHR 122a and an MSHR control unit 122b. The MSHR 122a stores an address of a node (intermediate node) locked by the PAT cache 120 and a waiting list for each address.

The MSHR control unit 122b controls registration of the address of the node and the waiting list in the MSHR 122a. In a case where the requested node (intermediate node) is not cached and is not registered in the MSHR 122a, the MSHR control unit 122b registers the requested address in the MSHR 122a to lock the intermediate node, requests the node from the authenticator 130, and returns the request to the PAT requester 110. In a case where the number of addresses registered in the MSHR 122a reaches the upper limit, the MSHR control unit 122b sets the block unit 121 to the block state. In other words, in a case where the number of addresses registered in the MSHR 122a reaches the upper limit, the block unit 121 is set to the block state, so that the block unit 121 blocks the request input to the PAT cache 120.

In a case where the requested node (intermediate node) is not cached but registered in the MSHR 122a, the MSHR control unit 122b writes a request in the waiting list of the relevant address and returns the request to the PAT requester 110. In a case where the length of the waiting list reaches a predetermined threshold, the MSHR control unit 122b sets the block unit 112 of the PAT requester 110 to the block state. In other words, in a case where the length of the waiting list of the MSHR 122a reaches the predetermined threshold, the block unit 112 of the PAT requester 110 is set to the block state, so that the block unit 112 blocks the request input to the PAT requester 110.

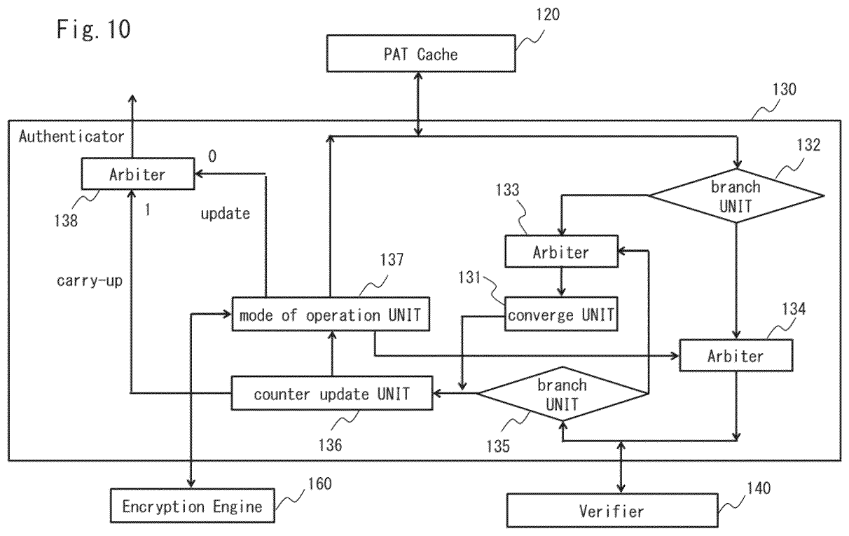

FIG. 10 is a block diagram illustrating a detailed configuration example of the authenticator 130 according to some example embodiments. In the example of FIG. 10, the authenticator 130 includes a converge unit 131, a branch unit 132, an arbiter 133, an arbiter 134, a branch unit 135, a counter update unit 136, a mode-of-operation unit 137, and an arbiter 138.

The branch unit 132 receives the node request and the write-back node from the PAT cache 120, sends the write-back node to the converge unit 131 (arbiter 133), and sends the others to the verifier 140 (arbiter 134).

The arbiter 133 accepts a request from the branch unit 132 and a request from the branch unit 135, and in a case where the requests conflict with each other, processes the requests according to the priority order. Either the request from the branch unit 132 or the request from the branch unit 135 may be prioritized.

The converge unit (node storage unit) 131 stores the write-back node received from the PAT cache 120 and sends the stored node to the counter update unit 136.

The branch unit 135 receives the verified node from the verifier 140, sends the node to be updated to the counter update unit 136, and sends the others to the converge unit 131 (arbiter 133).

The counter update unit 136 updates the counter of the node. In a case where a carry-up request is required, the counter update unit 136 sends the carry-up request to the PAT requester 110 (arbiter 138).

The mode-of-operation unit (authentication tag generation unit) 137 generates an authentication tag using an encryption engine and sends the node in which the authentication tag is generated to the PAT cache 120. In a case where the update request is required, the mode-of-operation unit 137 sends the update request to the PAT requester 110 (arbiter 138).

The arbiter 134 accepts the request of the node from the PAT cache 120 and the request of the node from the mode-of-operation unit 137, and processes the requests according to the priority order in a case where the requests conflict. Either the request of the node from the PAT cache 120 or the request of the node from the mode-of-operation unit 137 may be prioritized.

The arbiter 138 accepts the carry-up request from the counter update unit 136 and the update request from the mode-of-operation unit 137, and processes the requests according to the priority order in a case where the requests conflict with each other. For example, the priority order of the update request from the mode-of-operation unit 137 is higher than the priority order of the carry-up request from the counter update unit 136.

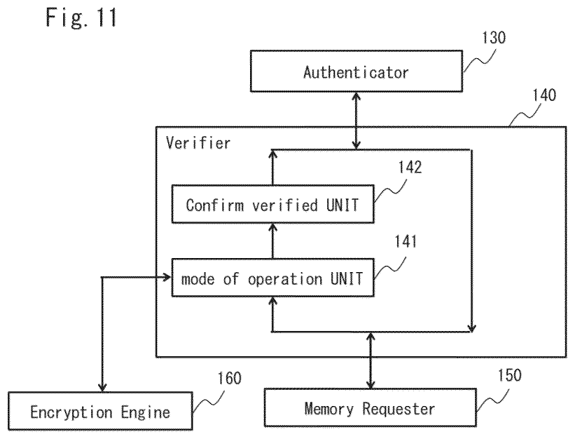

FIG. 11 is a block diagram illustrating a detailed configuration example of the verifier 140 according to some example embodiments. In the example of FIG. 11, the verifier 140 includes a mode-of-operation unit 141 and a confirm verified unit 142.

The mode-of-operation unit (node verification unit) 141 receives a response from the memory requester 150, and verifies the node (data) of the received response using the encryption engine 160.

The confirm verified unit (flag confirmation unit) 142 sets a flag indicating verified to the verified node, confirms that the verified flag is set, and transmits the verified node to the authenticator 130.

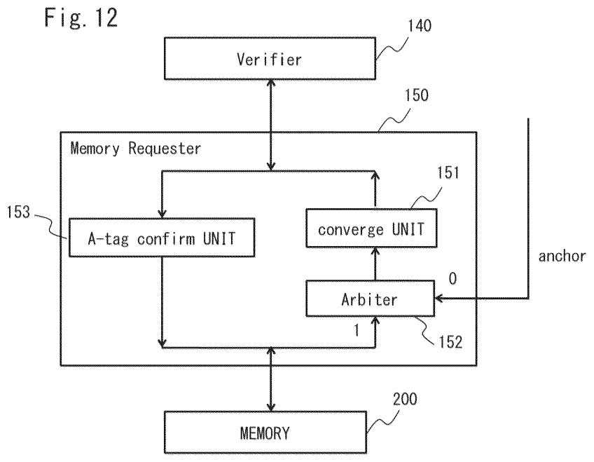

FIG. 12 is a block diagram illustrating a detailed configuration example of the memory requester 150 according to some example embodiments. In the example of FIG. 12, the memory requester 150 includes a converge unit 151, an arbiter 152, and an A-tag confirm unit 153.

The arbiter 152 accepts a request (node) from the traverse unit 115 of the PAT requester 110 and a response from the memory 200, and processes the request and the response according to the priority order in a case where the request and the response conflict with each other. For example, the priority order of the request from the traverse unit 115 is higher than the priority order of the response from the memory 200.

The converge unit (node storage unit) 151 stores the node (anchor) received from the traverse unit 115. The converge unit 151 stores a node (data) of the response received from the memory 200.

The A-tag confirm unit (authentication tag confirmation unit) 153 receives a request from the verifier 140 (authenticator 130) and sends the received request to the memory 200. In a case where the received request includes data, the A-tag confirm unit 153 confirms that a flag indicating that an authentication tag is attached is set.

### <Operation of Memory Integrity Confirmation Unit>

Next, an operation example in each unit of the memory integrity confirmation unit 100 will be described.

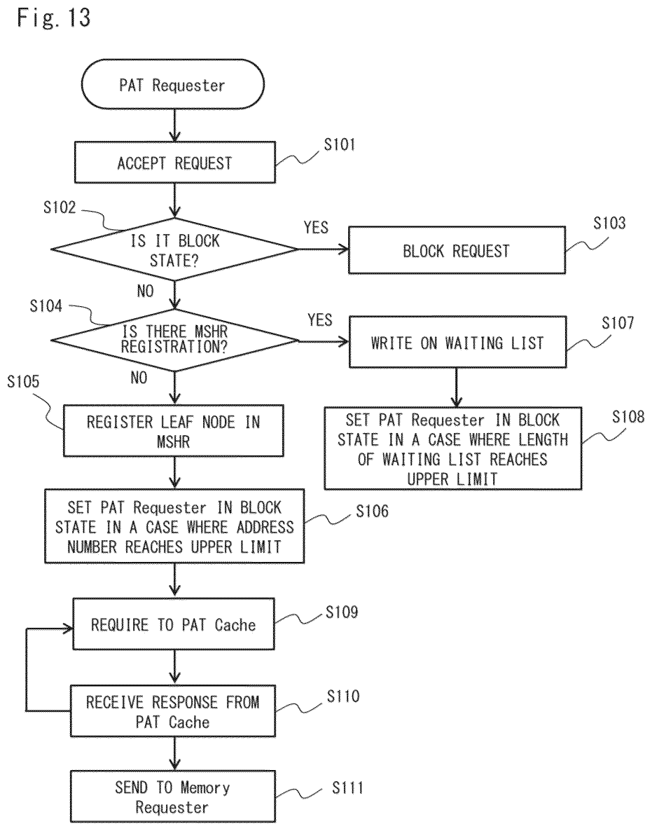

FIG. 13 is a flowchart illustrating an operation example of the PAT requester 110 illustrated in FIG. 8.

In the example of FIG. 13, the arbiter 111 accepts a request from the LLC 300 (LLC bus 301), the PAT cache 120, or the authenticator 130 (S101). For example, the arbiter 111 accepts, from the LLC 300 (LLC bus 301), a request for a process of reading a cache line from the memory 200 to the data cache (LLC 300) and a request for writing a cache line from the data cache to the memory 200. These requests relate to data stored in the data cache and thus relate to leaf nodes. The arbiter 111 compares the request from the LLC 300 with the request from the others, and accepts the request from the LLC 300 with the lowest priority order (3). That is, if there is another request, the arbiter 111 executes the another request earlier than the request from the LLC 300.

Subsequently, the block unit 112 determines whether it is in the block state (S102). In a case where it is in the block state (blocking), the block unit blocks the request from the arbiter 111 (S103). In a case where it is not in the block state, the block unit sends the request from the arbiter 111 to the MSHR unit 113.

In a case where the block unit 112 is not in the block state, the MSHR control unit 113b determines whether the address of the requested node is registered in the MSHR 113a (whether it is locked) (S104). In other words, it is determined whether a past request related to the same address (leaf node) has been completed.

In a case where the requested address (leaf node) is not registered in the MSHR 113a (in a case where there is no past request that has not been completed for the same leaf node), the MSHR control unit 113b registers and locks the requested address (leaf node) in the MSHR 113a (S105), and sends the request to the command processing unit 114. At this time, in a case where the number of addresses registered in the MSHR 113a reaches the upper limit, the MSHR control unit 113b sets the block unit 112 to the block state (S106).

In a case where the requested address (leaf node) is registered in the MSHR 113a (in a case where a past request related to the same leaf node has not been completed), the MSHR control unit 113b writes a request in a waiting list of the relevant address (S107), and this request enters a waiting state. At this time, in a case where the length of the waiting list reaches the upper limit, the MSHR control unit 113b sets the block unit 112 to the block state (S108).

After the leaf node is registered in the MSHR 113a in S105, the command processing unit 114 executes the requested processing (each command processing), and sends a request (node) based on each command to the PAT cache 120 (S109).

For example, the leaf processing unit 114a processes a request related to a leaf node from the LLC 300. The leaf processing unit 114a requests the leaf node requested by the LLC 300, the node including the counter, and the node including the authentication tag in the case of a read request (the authentication tag is not requested in the case of a write request) from the PAT cache 120.

After requesting the PAT cache 120 from the leaf processing unit 114a, the traverse unit 115 receives a response from the PAT cache 120 (S110). If the response received from the PAT cache 120 includes the cache line read from the PAT cache 120, the traverse unit 115 sends information of the response (information (anchor) of the hit node) to the memory requester 150 (S111). If the response received from the PAT cache 120 indicates that the node is registered in the MSHR 122a of the PAT cache 120, the traverse unit 115 sends information of the response (information indicating that the node is registered in the MSHR 122a) to the memory requester 150 (S111).

If the response received from the PAT cache 120 relates to a counter node, is not cached, and is not registered in the MSHR 122a of the PAT cache 120, the traverse unit 115 derives an identifier of a parent node of this node, and requests the derived node from the PAT cache 120 (S109). In a case where the request from the traverse unit 115 and the request from the command processing unit 114 conflict with each other, the arbiter 116 executes the request from the traverse unit 115.

After making the request from the traverse unit 115 to the PAT cache 120, the traverse unit 115 receives a response from the PAT cache 120 similarly to the request from the leaf processing unit 114a (S110). The request from the traverse unit 115 and the response from the PAT cache 120 (S109 to S110) are repeated until the node existing in the PAT cache 120 or the node registered in the MSHR 122a of the PAT cache 120 is encountered. For example, in the case of FIG. 5, the first access is repeated up to the nodes N1 to N4 (up to the cached node N4), and the second access is repeated up to the nodes N6, N7, and N3 (up to the node N3 registered with the MSHR 122a).

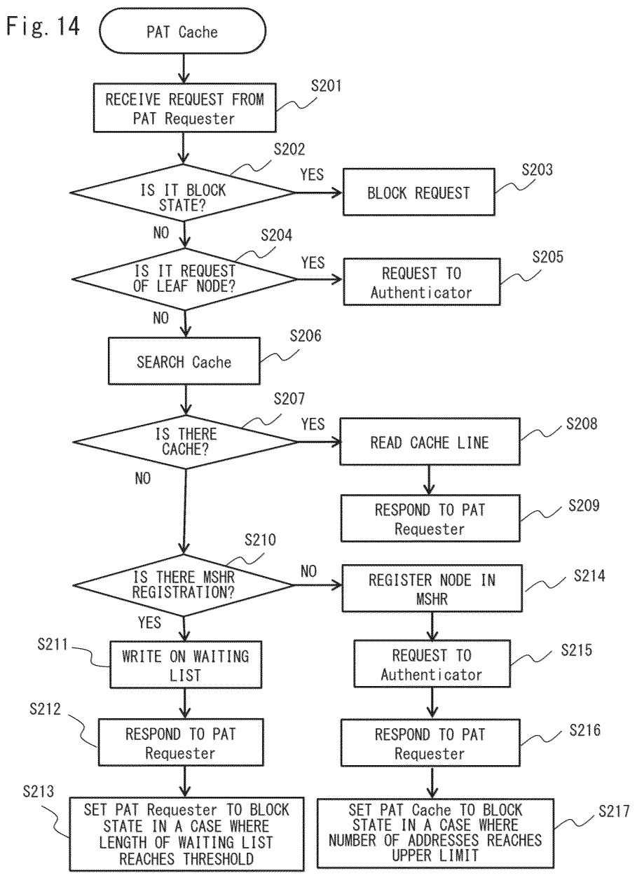

FIG. 14 is a flowchart illustrating an operation example of the PAT cache 120 illustrated in FIG. 9. FIG. 14 illustrates an operation example in a case where a request is accepted from the PAT requester 110.

In the example of FIG. 14, in a case of receiving the request from the PAT requester 110 (S201), the block unit 121 determines whether it is in the block state (S202), blocks the request from the PAT requester 110 in the case of the block state (S203), and sends the request from the PAT requester 110 to the cache unit 123 in the case of not being in the block state.

In a case where the block unit 121 is not in the block state, the cache control unit 123b determines whether the requested node is a leaf node (S204). In a case where the requested node is a leaf node, the cache control unit 123b directly transmits a request to the authenticator 130 (S205). In a case where the requested node is not a leaf node, the cache 123a searches for the leaf node (S206).

As a result of the search, the cache control unit 123b determines whether the requested node is cached (whether the requested node is stored in the cache 123a) (S207). In a case where the requested node is cached, the cache line is read from the cache 123a (S208). In a case where the node is updated, the data cached at the time of reading is updated. Further, the cache control unit 123b returns (responds) the read result to the PAT requester 110 (S209). This response is received by the traverse unit 115 as described above.

In a case where the requested node is not cached, the cache control unit 123b sends a request to the MSHR control unit 122b, and the MSHR control unit 122b determines whether the address of the requested node is registered in the MSHR 122a (whether it is locked) (S210).

In a case where the requested node is not cached but is registered in the MSHR 122a, the MSHR control unit 122b writes a request in the waiting list of the registered nodes (S211), and this request enters a waiting state. Further, the MSHR control unit 122b replies (responds) to the PAT requester 110 that the requested node is not cached but is registered in the MSHR 122a (S212). This response is received by the traverse unit 115 as described above. At this time, in a case where the length of the waiting list has reached the predetermined threshold, the MSHR control unit 122b sets the block unit 112 of the PAT requester 110 to the block state (S213).

In a case where the requested node is not cached and is not registered in the MSHR 122a, the MSHR control unit 122b registers the requested node in the MSHR 122a (S214), and requests the node from the authenticator 130 (S215). At the same time, in the case of the counter node, the MSHR control unit 122b replies (responds) to the PAT requester 110 that the requested node is not cached and is not registered in the MSHR 122a (S216). This response is received by the traverse unit 115 as described above. At this time, in a case where the number of addresses registered in the MSHR 113a reaches the upper limit, the MSHR control unit 122b sets the block unit 121 to the block state (S217).

As described above, in response to the request from the PAT requester 110, in the PAT cache 120, a process of registering the node in the MSHR 122a and a process of registering the registered node in the waiting list may occur. Here, since there is a limit to the number of nodes that can be registered in the MSHR 122a, the number of nodes may reach this limit. In this case, the MSHR control unit 122b changes the block unit 121 of the PAT cache 120 to the block state (S217). Thereafter, until the block state of the block unit 121 is released, the PAT cache 120 does not accept a new request from the PAT requester 110. Processing related to one leaf node is related to a plurality of nodes by reciprocating between the PAT cache 120 and the traverse unit 115. If all the plurality of related nodes are not collected (if all the processing of the plurality of nodes is not performed), the processing related to the first node is not completed. If these nodes cannot be collected due to the block state of the block unit 121, the processing is not completed, and the node locked in association cannot be released. This may cause a certain block to prevent unlocking of all other locks, create no room for the MSHR 122a to register a new node, and may lead to a deadlock. However, if the number of nodes that can be registered in the MSHR 122a is larger than the number of nodes related to an instruction in a state of reciprocating between the PAT cache 120 and the traverse unit 115, there is a process that can always complete and unlock the process, and the blocking can be resolved eventually.

In the process of writing on the waiting list, the waiting list of the nodes registered in the MSHR 122a may become insufficient. If the block unit 121 of the PAT cache 120 is set to the block state in order to prevent the list from overflowing, if the process of collecting the related nodes is not finished, the block unit 121 is in the block state, and thus the request to the PAT cache 120 is stopped, and deadlock occurs. Therefore, as described above, in a case where it is expected that the waiting list becomes insufficient, the block unit 112 of the PAT requester 110 is set to the block state (S213). In this case, since the block unit 121 of the PAT cache 120 is not brought into the block state, reciprocation of requests and responses between the PAT cache 120 and the traverse unit 115 is not prevented, and related nodes can be gathered. However, there may be multiple requests in this reciprocation state, which may be added to the waiting list. Therefore, the block request to the block unit 112 of the PAT requester 110 is performed while the waiting list has a certain margin (in a case where the length of the waiting list reaches a predetermined threshold). Preferentially completing this reciprocation minimizes consumption in the waiting list. Therefore, as described above, in the PAT requester 110, the arbiter 116 prioritizes the request from the traverse unit 115 over the request from the command processing unit 114. The block unit 112 of the PAT requester 110 handles the carry-up, update, and evict requests so as to be able to block the same in order to minimize consumption in the waiting list.

For example, in the case of FIG. 5, after the intermediate node N3 is registered (locked) to the MSHR 122a in accordance with the first access, the waiting list is written in the intermediate node N3 of the MSHR 122a in accordance with the second access. At this time, in a case where the length of the waiting list exceeds the threshold, the block unit 121 of the PAT cache 120 is not set to the block state, and the block unit 112 of the PAT requester 110 is set to the block state. As a result, the processing of the nodes N1 to N4 of the first access can be continued. Therefore, as illustrated in FIG. 6, after the processing of the nodes N1 to N4 of the first access is completed and the nodes N1 to N4 are unlocked, the processing of the nodes N6, N7, N3, and N4 of the second access can be performed.

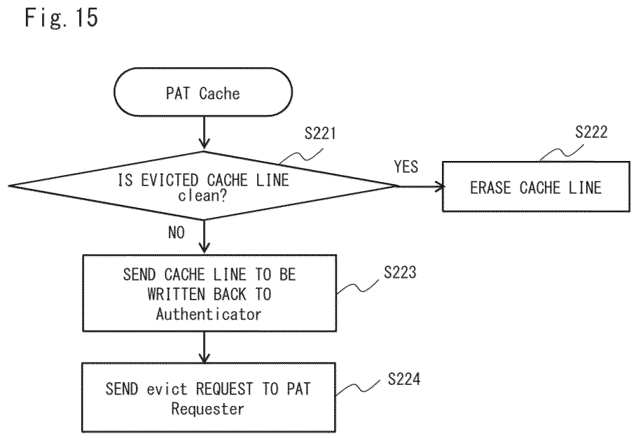

FIG. 15 is a flowchart illustrating another operation example of the PAT cache 120 illustrated in FIG. 9. The PAT cache 120 may evict a cache line which is an element of the cache 123a. This is to make room for reading and storing a new cache line from the memory 200. FIG. 15 illustrates an operation example in a case where the cache line is evicted from the cache 123a.

In the example of FIG. 15, in a case where the cache line is evicted from the cache 123a, the cache control unit 123b determines whether the evicted cache line is clean (S221). In a case where the cache line to be excluded is clean, that is, a case where the same data as the cache line is stored in the memory 200, the cache control unit 123b erases the cache line from the cache 123a (S222). As a result, it is possible to make a space for reading and storing a new cache line from the memory 200.

In a case where the cache line to be evicted is dirty, that is, in a case where data is changed after being read from the memory 200, the cache control unit 123b needs to write the cache line back to the memory 200. This write-back method is similar to a method of writing a leaf node from the LLC 300 back to the memory 200.

That is, first, the cache control unit 123b sends the cache line to be written back to the authenticator 130 (S223). This is the same as a case where the PAT requester 110 receives a write-back request of a certain leaf node from the LLC 300, and this node is sent to the authenticator 130 via the PAT cache 120. Further, the cache control unit 123b sends the address of the node sent to the authenticator 130 to the arbiter 111 of the PAT requester 110 together with an evict (eviction) request (S224).

In the PAT requester 110, similarly to the request of the leaf node, the evict request passes through the block unit 112 and the MSHR unit 113 and is sent to the evict processing unit 114d. The evict processing unit 114d derives an identifier of a parent node of the evicted node and sends the identifier to the PAT cache 120. Thereafter, as in the case of the request of the leaf node, the process of reciprocating between the traverse unit 115 and the PAT cache 120 is executed until the ancestor node encounters one cached in the PAT cache 120 or one registered in the MSHR 122a of the PAT cache 120.

Here, since the evict (eviction) request passes through the block unit 112 of the PAT requester 110, if the vacancy of the waiting list of a certain node registered in the MSHR 122a of the PAT cache 120 decreases and the block unit 112 is blocked, the evict request is not executed by the PAT requester 110, and the waiting list with a small vacancy is not squeezed.

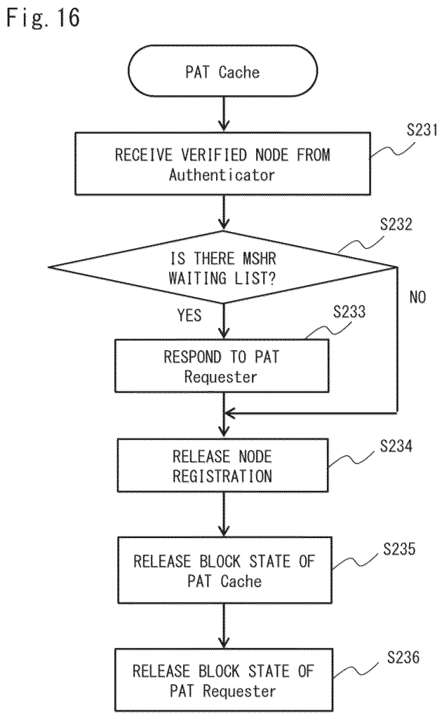

FIG. 16 is a flowchart illustrating another operation example of the PAT cache 120 illustrated in FIG. 9. FIG. 16 illustrates an operation example in a case where the PAT cache 120 requests the authenticator 130 and then receives a verified node from the authenticator 130.

In the example of FIG. 16, after receiving a verified node from the authenticator 130 (S231), the MSHR control unit 122b determines whether there is a request in the waiting list of nodes since this node is a node registered in the MSHR 122a (S232). In a case where there is a request in the waiting list of the registered node, the MSHR control unit 122b sends the node to the traverse unit 115 of the PAT requester 110 in order to respond to the request of the waiting list (S233).

The cache control unit 123b may store the verified node in the cache 123a. This storage may cause evict (eviction) of other cache lines. The node to be stored may be updated in response to the request for the waiting list.

Further, the MSHR control unit 122b cancels the registration of the verified node to the MSHR 122a (S234). That is, the address of the verified node is deleted from the MSHR 122a. In a case where the block unit 121 is set to the block state because the registration number of the MSHR 122a has reached the limit, the MSHR control unit 122b releases the block state (S235). That is, the block unit 121 is set to the non-block state.

With the deregistration of the node to the MSHR 122a, the waiting list of the node disappears. Therefore, if the block unit 112 of the PAT requester 110 is set to the block state by the length of the waiting list of this node, the MSHR control unit 122b releases this block state (S236). That is, the block unit 112 is set to the non-block state.

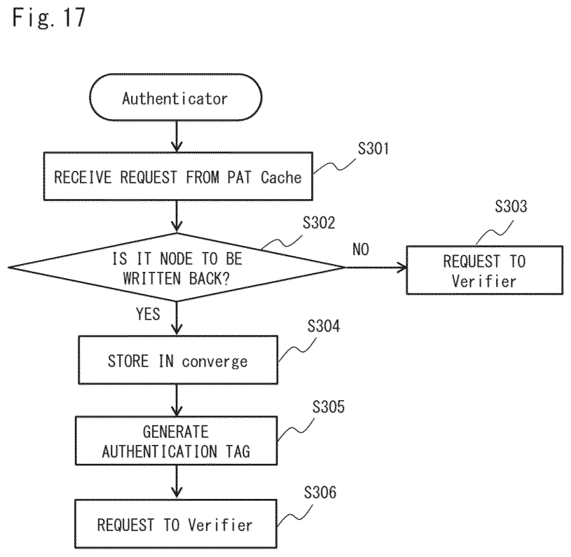

FIG. 17 is a flowchart illustrating an operation example of the authenticator 130 illustrated in FIG. 10. FIG. 17 illustrates an operation example in a case where a node request or a node to be written back is received from the PAT cache 120.

In the example of FIG. 17, after receiving a request from the PAT cache 120 (S301), the branch unit 132 determines whether a write-back node has been received (S302), and in a case of a node other than the write-back node (node request), the branch unit sends the node request to the verifier 140 (S303).

In a case where the node to be written back is received, the node to be written back to the converge unit 131 is sent from the branch unit 132, and the converge unit 131 stores the node to be written back (S304).

Thereafter, the mode-of-operation unit 137 generates an authentication tag for the node stored in the converge unit 131 using the cryptographic protocol (S305). A flag indicating attachment of an authentication tag is attached to the node in which the authentication tag is generated. Further, the mode-of-operation unit 137 sends the node to which the authentication tag is attached to the verifier 140 via the arbiter 134 (S306).

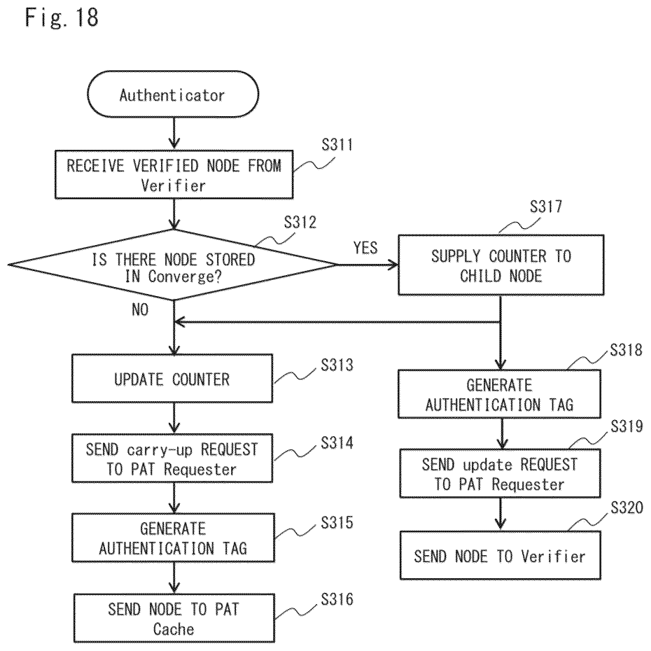

FIG. 18 is a flowchart illustrating another operation example of the authenticator 130 illustrated in FIG. 10. FIG. 18 illustrates an operation example in a case where the authenticator 130 requests the verifier 140 and then a verified node is received from the verifier 140.

In the example of FIG. 18, after receiving a verified node from the verifier 140 (S311), the branch unit 135 determines whether the received node is a node including a counter of a node stored in the converge unit 131 (S312).

In a case where the received node is not a node including the counter of the node stored in the converge unit 131, the branch unit 135 transmits the node to the counter update unit 136, and the counter update unit 136 increments the counter of the node in a case where the node is updated (S313). Here, in a case where the value of the minor counter reaches the upper limit, the counter update unit 136 sends a carry-up request to the PAT requester 110 (S314).

This request causes the PAT requester 110 to request the PAT cache 120 for a plurality of nodes. However, since the nodes are to be blocked by the block unit 112 of the PAT requester 110, in a case where the waiting list of the MSHR 122a of the PAT cache 120 is congested, the nodes are blocked by the block unit 112, and the request for reciprocating between the PAT cache 120 and the traverse unit 115 is not increased.

Thereafter, the mode-of-operation unit 137 generates an authentication tag for a node for which the authentication tag needs to be generated, using the encryption engine 160 (S315). Further, the mode-of-operation unit 137 sends the node for which the authentication tag is generated to the PAT cache 120 (S316).

In a case where the node received from the verifier 140 is a node including the counter of the node stored in the converge unit 131, the node is transmitted from the arbiter 133 to the converge unit 131, and the converge unit 131 supplies the counter of the received node to the child node stored in the converge unit 131 (S317). The received node is sent to the counter update unit 136, and then processed in the same manner as the node sent to the counter update unit 136 described above (S313 to S316).

The node to which the counter is supplied by the converge unit 131 is also sent to the counter update unit 136 together with the counter. Thereafter, an authentication tag is generated by the mode-of-operation unit 137 (S318). The mode-of-operation unit 137 sends the generated authentication tag (update request) to the arbiter 111 of the PAT requester 110 (S319). Further, the mode-of-operation unit 137 sends the node that has generated the authentication tag to the verifier 140 via the arbiter 134 (S320). Thereafter, the data is written back from the verifier 140 to the memory 200 via the memory requester 150.

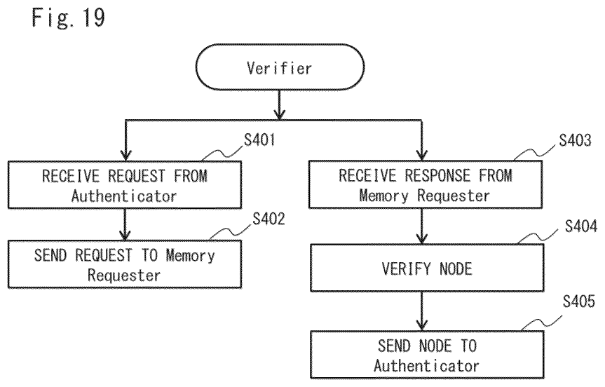

FIG. 19 is a flowchart illustrating an operation example of the verifier 140 illustrated in FIG. 11. FIG. 19 illustrates an operation example in a case where the verifier 140 receives a request from the authenticator 130, and in a case where the verifier receives a response from the memory requester 150 after requesting the memory requester 150.

In the example of FIG. 19, in a case of receiving a request from the authenticator 130 (S401), the verifier 140 sends the received request as it is to the memory requester 150 (S402).

In a case of receiving the response from the memory requester 150 (S403), the mode-of-operation unit 141 verifies the node of the received response according to the cryptographic protocol using the encryption engine 160 (S404).

Subsequently, the confirm verified unit 142 sets a flag indicating verified to the verified node and sends the node to the authenticator 130 (S405). The confirm verified unit 142 confirms that the verified flag is set immediately before the transmission.

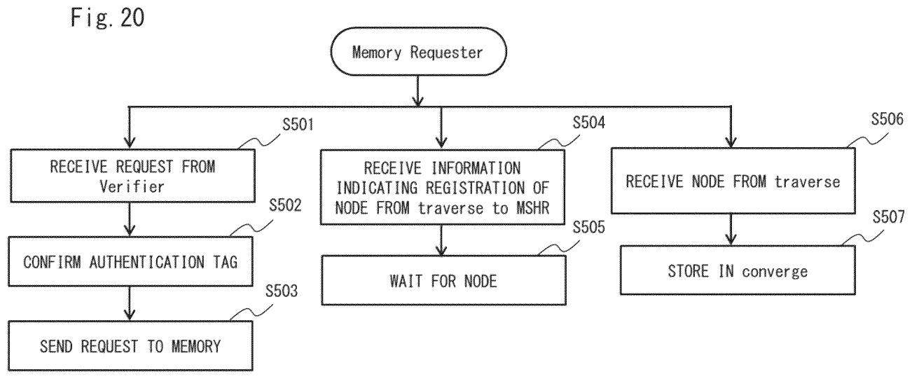

FIG. 20 is a flowchart illustrating an operation example of the memory requester 150 illustrated in FIG. 12. FIG. 20 illustrates an operation example in a case where a request is received from the traverse unit 115 of the authenticator 130 or the PAT requester 110.

In the example of FIG. 20, in a case of receiving a request from the authenticator 130 (S501), in a case where the received request is accompanied with data, the A-tag confirm unit 153 confirms that a flag indicating that an authentication tag is attached is set (S502) and sends the received request to the memory 200 (S503). The A-tag confirm unit 153 also sends the received request to the memory 200 in a case where the request is not accompanied with data. In other cases, the A-tag confirm unit 153 causes an error.

In a case of receiving information indicating that a certain node is registered in the MSHR from the traverse unit 115 of the PAT requester 110 (S504), the converge unit 151 understands that this node will come and waits for this node to come from the authenticator 130 (S505). That is, what is closest to the ancestor of the associated set of nodes is known.

In a case of receiving a certain node (anchor) from the traverse unit 115 of the PAT requester 110 (S506), the converge unit 151 stores the received node (S507). At this time, the node received from the PAT requester 110 has been verified.

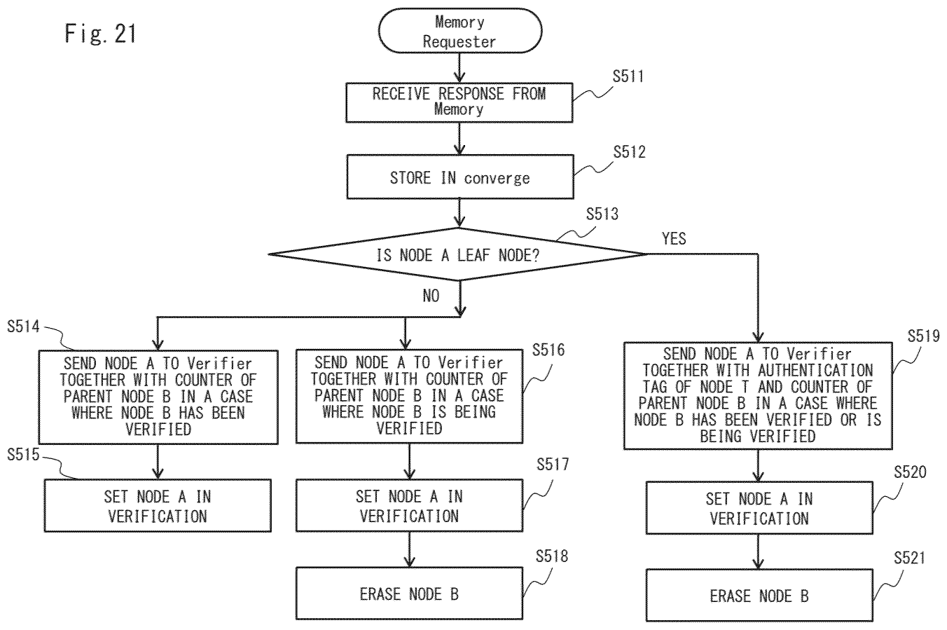

FIG. 21 is a flowchart illustrating another operation example of the memory requester 150 illustrated in FIG. 12. FIG. 21 illustrates an operation example in a case where the memory requester 150 requests the memory 200 and receives a response from the memory 200.

In the example of FIG. 21, after receiving the response from the memory 200 (S511), the converge unit 151 stores the received response (S512). The converge unit 151 processes each stored node A as follows.

The converge unit 151 determines whether the node A is a leaf node (S513), and in a case where the node A is not a leaf node, the parent node B of the node A is also stored, and the node B has been verified, extracts a counter of the node A from the node B, and sends the counter and the extracted counter of the node A to the verifier 140 for verification (S514). The converge unit 151 determines that the node A is being verified (S515).

In a case where the node A is not a leaf node, the parent node B of the node A is also stored, and the node B is being verified, the converge unit 151 extracts the counter of the node A from the node B, and sends the counter of the node A together with the extracted counter to the verifier 140 for verification (S516). The converge unit 151 determines that the node A is being verified (S517), and erases the node B (S518).

In a case where the node A is a leaf node, the node T including the authentication tag of the node A and the parent node B including the counter of the node A are also stored, and the node B has been verified or is being verified, the converge unit 151 extracts the authentication tag of the node A (leaf node) from the node T, extracts the counter of the node A from the node B, and sends the counter together with the extracted authentication tag of the node A and the extracted counter to the verifier 140 for verification (S519). The converge unit 151 determines that the node A (leaf node) is being verified (S520), and erases the node B (S521).

### <Effects>

As described above, the memory integrity confirmation unit according to the present example embodiment includes a mechanism (PAT requester) including a mechanism (traverse) for sequentially tracing an ancestor node from a node given in the integrity tree, a cache (PAT Cache) capable of temporarily storing a node of the integrity tree, and a mechanism (Authenticator) for generating an authentication tag. In the memory integrity confirmation unit, the PAT cache performs control to lock access to the same node by the PAT requester by the MSHR. If the number of nodes that can be registered in the MSHR becomes insufficient due to this lock, the request receiver on the PAT requester side of the PAT Cache is set to the block state. Further, if the number of requests (waiting lists) for waiting for nodes registered in the MSHR becomes larger than a certain number, the PAT requester is put into a block state. As a result, even if the number of requests for waiting for a certain node registered in the MSHR of the PAT cache increases by a certain number or more, new processing is not increased, and the search of the integrity tree is not stopped. This makes it possible to prevent cache deadlock while reducing the MSHR space.

The present disclosure is not limited to the above-described example embodiments, and can be appropriately modified without departing from the scope.

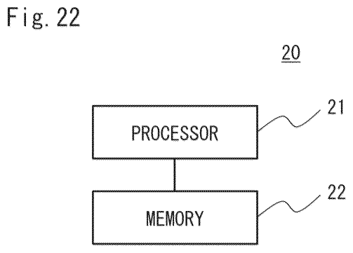

Each configuration in the above-described example embodiments may be implemented by hardware, software, or both, and may be implemented by one piece of hardware or software or by a plurality of pieces of hardware or software. Function (process) of the information processing device including the memory integrity confirmation unit (device) may be implemented by a computer 20 including a processor 21 such as a central processing unit (CPU) and a memory 22 which is a storage device as illustrated in FIG. 22. For example, a program for performing the integrity confirmation method in the example embodiment may be stored in the memory 22, and each function may be achieved by executing the program stored in the memory 22 by the processor 21.

The program described above includes commands (or software codes) for causing a computer to perform one or more functions described in the example embodiments in a case where the program is read by the computer. The program may be stored in a non-transitory computer readable medium or a tangible storage medium. As an example and not by way of limitation, a computer readable medium or tangible storage medium includes a random-access memory (RAM), a read-only memory (ROM), a flash memory, a solid-state drive (SSD) or other memory technology, a CD-ROM, a digital versatile disc (DVD), a Blu-ray (registered trademark) disk, or other optical disk storages, a magnetic cassette, a magnetic tape, a magnetic disk storage, or other magnetic storage devices. The program may be transmitted on a transitory computer readable medium or a communications medium. As an example and not by way of limitation, the transitory computer readable medium or the communication medium includes electrical, optical, acoustic, or other forms of propagated signals.

While the present disclosure has been particularly shown and described with reference to example embodiments thereof, the present disclosure is not limited to these example embodiments. It will be understood by those of ordinary skill in the art that various changes in form and details may be made therein without departing from the spirit and scope of the present disclosure as defined by the claims. And each embodiment can be appropriately combined with other embodiments.

Each of the drawings is merely an example to illustrate one or more example embodiments. Each of the drawings is not associated with only one specific example embodiment, but may be associated with one or more other example embodiments. As those ordinary skilled in the art will appreciate, various features or steps described with reference to any one of the drawings may be combined with features or steps illustrated in one or more other drawings, for example, to create an example embodiment that is not explicitly illustrated or described. All of the features or steps illustrated in any one of the figures for explaining illustrative example embodiments are not necessarily mandatory, and some features or steps may be omitted. The order of the steps described in any of the figures may be changed as appropriate.

Some or all of the example embodiments described above may be described as, but are not limited to, the following Supplementary Notes.

### Supplementary Note 1

A memory integrity confirmation device that confirms integrity of data between a cache memory and a memory, the device including:
a tree cache that temporarily stores data allocated to nodes in an integrity tree including the nodes arranged in a tree shape; and
a request processing unit that accepts a request for a leaf node in the integrity tree from the cache memory and requests the tree cache to search for an intermediate node from the leaf node to a root node in the integrity tree, in which
the tree cache includes a first registration unit that locks the intermediate node to exclusively control the search request for a same intermediate node, and registers a wait request for each locked intermediate node, and
the request processing unit includes a first block unit that blocks a request accepted by the request processing unit in accordance with a number of the registered wait requests in the first registration unit.

### Supplementary Note 2

The memory integrity confirmation device according to Supplementary Note 1, in which
the first block unit blocks a request accepted in the request processing unit in a case where the number of the registered wait requests in the first registration unit is larger than a predetermined threshold, and
the predetermined threshold is smaller than a maximum value of a number of the wait requests that can be registered in the first registration unit.

### Supplementary Note 3

The memory integrity confirmation device according to Supplementary Note 1 or 2, in which the tree cache includes a second block unit that blocks a request accepted in the tree cache according to a number of the locked intermediate nodes in the first registration unit.

### Supplementary Note 4

The memory integrity confirmation device according to Supplementary Note 3, in which the second block unit blocks a request accepted in the tree cache in a case where a number of the locked intermediate nodes in the first registration unit reaches a maximum value of the number of the intermediate nodes that can be locked in the first registration unit.

### Supplementary Note 5

The memory integrity confirmation device according to Supplementary Note 1 or 2, in which the first registration unit is a miss status holding register (MSHR).

### Supplementary Note 6

The memory integrity confirmation device according to Supplementary Note 1 or 2, in which the request processing unit includes a second registration unit that locks the leaf node to exclusively control a request from the cache memory to a same leaf node and registers a wait request for each locked leaf node.

### Supplementary Note 7

The memory integrity confirmation device according to Supplementary Note 6, in which the first block unit blocks a request accepted by the request processing unit according to a number of the locked leaf nodes in the second registration unit or a number of the registered wait requests in the second registration unit.

### Supplementary Note 8

The memory integrity confirmation device according to Supplementary Note 7, in which the first block unit blocks a request accepted in the request processing unit in a case where a number of the locked leaf nodes in the second registration unit reaches a maximum value of a number of the leaf nodes that can be locked in the second registration unit, or in a case where a number of wait requests registered in the second registration unit reaches a maximum value of a number of the wait requests that can be registered in the second registration unit.

### Supplementary Note 9

The memory integrity confirmation device according to Supplementary Note 6, in which the second registration unit is a miss status holding register (MSHR).

### Supplementary Note 10

The memory integrity confirmation device according to Supplementary Note 1 or 2, in which
the tree cache requests the request processing unit to evict the temporarily stored data, and
the request processing unit preferentially executes a request from the tree cache over a request from the cache memory.

### Supplementary Note 11

The memory integrity confirmation device according to Supplementary Note 1 or 2, including an authentication unit that generates an authentication tag allocated to the node and requests the request processing unit to update a counter allocated to the node,
in which the request processing unit preferentially executes a request from the authentication unit over a request from the cache memory.

### Supplementary Note 12

The memory integrity confirmation device according to Supplementary Note 1 or 2, in which in a case where a request for searching for the tree cache for the intermediate node and another request conflict with each other, the request processing unit preferentially executes the request for searching for the intermediate node over the another request.

### Supplementary Note 13

An information processing device including:
a cache memory;
a memory; and
a memory integrity confirmation unit that confirms integrity of data between the cache memory and the memory, wherein
the memory integrity confirmation unit includes:
   a tree cache that temporarily stores data allocated to nodes in an integrity tree including the nodes arranged in a tree shape; and
   a request processing unit that accepts a request for a leaf node in the integrity tree from the cache memory and requests the tree cache to search for an intermediate node from the leaf node to a root node in the integrity tree,
the tree cache includes a first registration unit that locks the intermediate node to exclusively control the search request for a same intermediate node, and registers a wait request for each locked intermediate node, and
the request processing unit includes a first block unit that blocks a request accepted by the request processing unit in accordance with a number of the registered wait requests in the first registration unit.

### Supplementary Note 14

A memory integrity confirmation method for confirming integrity of data between a cache memory and a memory, the method including:
temporarily storing, by a tree cache, data allocated to nodes in an integrity tree including the nodes arranged in a tree shape;
accepting, by a request processing unit, a request for a leaf node in the integrity tree from the cache memory and requesting the tree cache to search for an intermediate node from the leaf node to a root node in the integrity tree;
locking the intermediate node to exclusively control the search request for a same intermediate node, and registering a wait request for each locked intermediate node; and
blocking a request accepted by the request processing unit in accordance with a number of the registered wait requests.

### Supplementary Note 15

A program for a memory integrity confirmation device to confirm integrity of data between a cache memory and a memory, the program causing a computer to execute:
temporarily storing, by a tree cache, data allocated to nodes in an integrity tree including the nodes arranged in a tree shape;
accepting, by a request processing unit, a request for a leaf node in the integrity tree from the cache memory and requesting the tree cache to search for an intermediate node from the leaf node to a root node in the integrity tree;
locking the intermediate node to exclusively control the search request for a same intermediate node, and registering a wait request for each locked intermediate node; and
blocking a request accepted by the request processing unit in accordance with a number of the registered wait requests.

Some or all of the elements (for example, configurations and functions) described in Supplementary Notes 2 to 12 dependent on Supplementary Note 1 (memory integrity confirmation device) can also be dependent on Supplementary Note 13 (information processing device), Supplementary Note 14 (memory integrity confirmation method), and Supplementary Note 15 (program) by the same dependency relationship as Supplementary Notes 2 to 12. Some or all of the elements described in any Supplementary Note may be applied to various types of hardware components, software components, recording means for recording software components, systems, and methods.

What is claimed is:

1. A memory integrity confirmation device that confirms integrity of data between a cache memory and a memory, the device comprising:
a tree cache that temporarily stores data allocated to nodes in an integrity tree including the nodes arranged in a tree shape; and
a requester that accepts a request for a leaf node in the integrity tree from the cache memory and requests the tree cache to search for an intermediate node from the leaf node to a root node in the integrity tree, wherein
the tree cache includes a first register that locks the intermediate node to exclusively control the search request for a same intermediate node, and registers a wait request for each locked intermediate node, and
the requester blocks a request accepted by the requester in accordance with a number of the registered wait requests in the first register.

2. The memory integrity confirmation device according to claim 1, wherein
the requester blocks a request accepted in the requester in a case where the number of the registered wait requests in the first register is larger than a predetermined threshold, and
the predetermined threshold is smaller than a maximum value of a number of the wait requests that can be registered in the first register.

3. The memory integrity confirmation device according to claim 1, wherein the tree cache blocks a request accepted in the tree cache according to a number of the locked intermediate nodes in the first register.

4. The memory integrity confirmation device according to claim 3, wherein the tree cache blocks a request accepted in the tree cache in a case where a number of the locked intermediate nodes in the first register reaches a maximum value of the number of the intermediate nodes that can be locked in the first register.

5. The memory integrity confirmation device according to claim 1, wherein the first register is a miss status holding register (MSHR).

6. The memory integrity confirmation device according to claim 1, wherein the requester includes a second register that locks the leaf node to exclusively control a request from the cache memory to a same leaf node and registers a wait request for each locked leaf node.

7. The memory integrity confirmation device according to claim 6, wherein the requester blocks a request accepted by the requester according to a number of the locked leaf nodes in the second register or a number of the registered wait requests in the second register.

8. The memory integrity confirmation device according to claim 7, wherein the requester blocks a request accepted in the requester in a case where a number of the locked leaf nodes in the second register reaches a maximum value of a number of the leaf nodes that can be locked in the second register, or in a case where a number of wait requests registered in the second register reaches a maximum value of a number of the wait requests that can be registered in the second register.

9. The memory integrity confirmation device according to claim 6, wherein the second register is a miss status holding register (MSHR).

10. The memory integrity confirmation device according to claim 1, wherein
the tree cache requests the requester to evict the temporarily stored data, and
the requester preferentially executes a request from the tree cache over a request from the cache memory.

11. The memory integrity confirmation device according to claim 1, comprising an authenticator that generates an authentication tag allocated to the node and requests the requester to update a counter allocated to the node,
wherein the requester preferentially executes a request from the authenticator over a request from the cache memory.

12. The memory integrity confirmation device according to claim 1, wherein in a case where a request for searching for the tree cache for the intermediate node and another request conflict with each other, the requester executes the request for searching for the intermediate node over the another request.

13. An information processing device comprising:
a cache memory;
a memory; and
a memory integrity confirmation device that confirms integrity of data between the cache memory and the memory, wherein
the memory integrity confirmation device includes:
a tree cache that temporarily stores data allocated to nodes in an integrity tree including the nodes arranged in a tree shape; and
a requester that accepts a request for a leaf node in the integrity tree from the cache memory and requests the tree cache to search for an intermediate node from the leaf node to a root node in the integrity tree,
the tree cache includes a first register that locks the intermediate node to exclusively control the search request for a same intermediate node, and registers a wait request for each locked intermediate node, and
the requester blocks a request accepted by the requester in accordance with a number of the registered wait requests in the first register.

14. A memory integrity confirmation method for confirming integrity of data between a cache memory and a memory, the method comprising:
temporarily storing, by a tree cache, data allocated to nodes in an integrity tree including the nodes arranged in a tree shape;
accepting, by a requester, a request for a leaf node in the integrity tree from the cache memory and requesting the tree cache to search for an intermediate node from the leaf node to a root node in the integrity tree;
locking the intermediate node to exclusively control the search request for a same intermediate node, and registering a wait request for each locked intermediate node; and
blocking a request accepted by the requester in accordance with a number of the registered wait requests.
